(19) United States
(12) Patent Application Publication
(10) Pub. No.: US 2026/0214910 A1
(43) Pub. Date: Jul. 23, 2026

(54) MAGNETIC MEMORY

(71) Applicant: Kioxia Corporation, Tokyo (JP)

(72) Inventor: Yoshihiro UEDA, Yokohama (JP)

(73) Assignee: Kioxia Corporation, Tokyo (JP)

(21) Appl. No.: 19/326,754

(22) Filed: Sep. 12, 2025

(30) Foreign Application Priority Data
Jan. 20, 2025 (JP) 2025-008043

(51) Int. Cl. H10B 61/00

(52) U.S. Cl. CPC H10B 61/20

(57) ABSTRACT

A magnetic memory includes a first write wire, a first read on the first write wire, a second write wire and a second read wire intersecting with the first write wire, a conductive wire, and a magnetoresistance element. One end of the magnetoresistance element is connected to the conductive wire. One of a source and a drain of a first transistor is connected to the second write wire, the other is connected to the conductive wire, and a gate is connected to the first write wire. One of a source and a drain of a second transistor is connected to the second read wire, the other is connected to the other end of the magnetoresistance element, and a gate is connected to the first read wire. The threshold voltage of the first transistor is lower than that of the second transistor.

### CROSS-REFERENCE TO RELATED APPLICATION

This application is based upon and claims the benefit of priority from Japanese Patent Application No. 2025-008043, filed Jan. 20, 2025, the entire contents of which are incorporated herein by reference.

### FIELD

Embodiments described herein relate generally to a magnetic memory.

### BACKGROUND

Magnetic memories (hereinafter, also referred to as a magnetoresistive random access memory (MRAM)) have been developed. A magnetic tunnel junction (MTJ) element is used as a storage element of the MRAM. A problem that has been associated with the MTJ element is that it is prone to degradation due to heat treatment in manufacturing processes.

### BRIEF DESCRIPTION OF THE DRAWINGS

FIG. 1 is a diagram illustrating an overview of a memory cell of an SOT-MRAM.

FIG. 2 is a diagram illustrating a write operation and a read operation of the memory cell.

FIG. 3 is a perspective view illustrating an example configuration of a magnetic memory according to a first embodiment.

FIG. 4 is a plan view illustrating an example configuration of the magnetic memory according to the first embodiment.

FIG. 5 is an equivalent circuit diagram illustrating an example configuration of the magnetic memory according to the first embodiment.

FIG. 6 is a conceptual diagram illustrating a data write operation.

FIG. 7 is a conceptual diagram illustrating a data write operation.

FIG. 8 is a conceptual diagram illustrating a data read operation.

### DETAILED DESCRIPTION

An object is to inhibit degradation caused by heat and provide a highly reliable magnetic memory.

In general, according to one embodiment, a magnetic memory includes a first write wire. A first read wire is provided in a first direction relative to the first write wire. A second write wire intersects with the first write wire when viewed from the first direction (e.g., along the first direction or in a plan view). A second read wire intersects with the first read wire when viewed from the first direction. A conductive wire is electrically conductive. One end of a magnetoresistance element is connected to the conductive wire. One of a source and a drain of a first transistor is connected to the second write wire, the other is connected to the conductive wire, and a gate is connected to the first write wire. One of a source and a drain of a second transistor is connected to the second read wire, the other is connected to the other end of the magnetoresistance element, and a gate is connected to the first read wire. The threshold voltage of the first transistor is lower than the threshold voltage of the second transistor.

Embodiments according to the present invention will now be described with reference to drawings. The embodiments are not intended to limit the present invention. The drawings are schematic and conceptual. Throughout the specification and the drawings, like elements are given like reference signs.

### First Embodiment

A magnetic memory according to the first embodiment is a magnetic memory that takes advantage of a spin Hall effect or spin-obit coupling, that is, an SOT-MRAM in which a magnetization direction of a storage layer is reversed by a spin-orbit torque (SOT). Hereinunder, an example in which the embodiment is applied to the SOT-MRAM will be described. Note that, the embodiment is also applicable to 3-terminal MRAMs such as a magnetic domain wall MRAM.

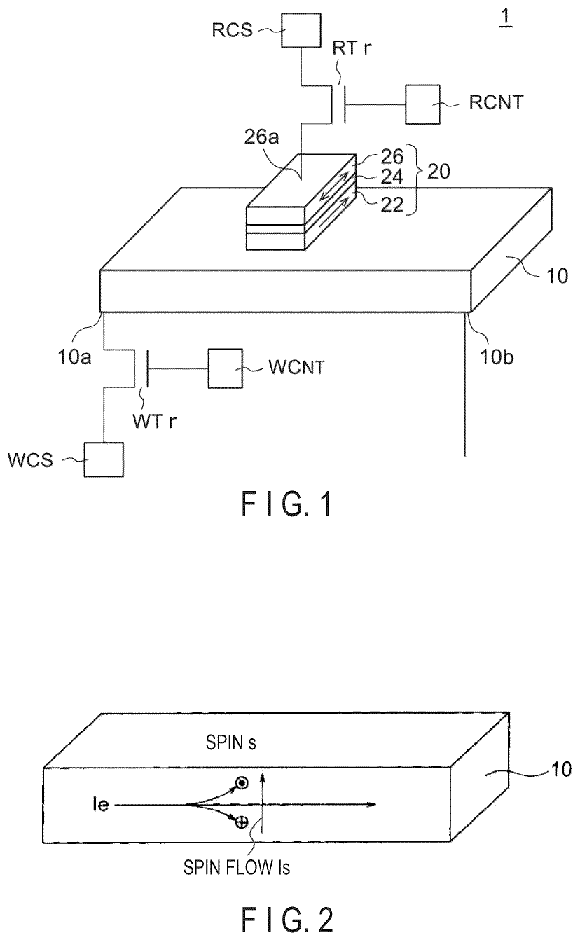

FIG. 1 is a diagram illustrating an overview of a magnetic memory 1. The magnetic memory 1 is, for example, an SOT-MRAM. The magnetic memory 1 includes at least one memory cell. The memory cell of the magnetic memory 1 includes an electrically conductive non-magnetic wire 10 that includes a first terminal 10a and a second terminal 10b, a magnetoresistance element (hereinafter also referred to as an MTJ element) 20 provided on a conductive wire 10, a write transistor WTr, and a read transistor RTr. The MTJ element 20 is provided on the conductive wire 10 and has a stacked structure with a storage layer 22, a non-magnetic layer 24, and a reference layer 26 stacked in this order. The storage layer 22 and the reference layer 26 are made of magnetic material. The storage layer 22 is a magnetic material layer, the magnetization direction of which can be changed in response to the direction of a current flowing through the conductive wire 10. The reference layer 26 is a magnetic material layer, the magnetization direction of which is fixed. The write transistor WTr is connected to the first terminal 10a of the conductive wire 10 at one of the source and the drain. The reference layer 26 includes a terminal 26a, and one of the source and the drain of the read transistor RTr is connected to the terminal 26a. That is, the memory cell includes three terminals 10a, 10b, and 26a. Note that, in the case in which the embodiment is applied to a magnetic domain wall MRAM, the conductive wire 10 is an electrically conductive magnetic wire.

Next, a write operation and a read operation of the magnetic memory 1 will be described with reference to FIG. 1 and FIG. 2.

### (Write Operation)

The write operation is performed by causing a current to flow between the first terminal 10a and the second terminal 10b of the conductive wire 10. For example, as illustrated in FIG. 2, when an electron flow (opposite to a current) is caused from the left to the right on the paper through the conductive wire 10, electrons (for example, electrons with up-spin) of one of electrons with up-spin and electrons with down-spin flow in an upper skin of the conductive wire 10 and electrons of the other (for example, electrons with down-spin) flow in a lower skin of the conductive wire 10 due to spin-obit coupling. That is, electrons that are spin-polarized to one of up-spin and down-spin flow through the upper skin of the conductive wire 10 from the left to the right on the paper, and electrons that are spin-polarized to the other flow through the lower skin of the conductive wire 10. Consequently, a spin torque caused by electrons that are one-sidedly spin-polarized, flowing through the upper skin of the conductive wire 10, acts on the magnetization of the storage layer 22, and the magnetization direction of the storage layer 22 becomes reversible. The conductive wire 10 is a layer responsible for spin-obit coupling. When an electron flow (opposite to a current) is caused from the right to the left on the paper through the conductive wire 10, in contrast to the above-described case, for example, electrons with down-spin flow through the upper skin of the conductive wire 10 and electrons with up-spin flow through the lower skin of the conductive wire 10. Accordingly, the magnetization direction of the storage layer 22 can be reversed by the direction of the current flowing through the conductive wire 10.

To perform a write operation in the memory cell illustrated in FIG. 1, a write circuit WCNT first places the write transistor WTr to an on-state. The write circuit WCNT adjusts a voltage applied to the gate of the write transistor WTr, so that the write transistor WTr enters a conducting state (ON) or a non-conducting state (OFF). With the write transistor WTr entering an on-state, a write circuit WCS causes a write current to flow between the first terminal 10a and the second terminal 10b of the conductive wire 10. Since the write current flows in the in-plane direction of the conductive wire 10, the effect due to spin-obit coupling is produced. This causes a magnetic torque to act on the storage layer 22, allowing the magnetization direction of the storage layer 22 to be reversed, so that the write operation is achieved. The magnetization direction of the storage layer 22 is controlled by the direction of the current flowing through the conductive wire 10 to write data in the MTJ element 20.

### (Read Operation)

In the read operation, a read circuit RCNT first places the read transistor RTr to an on-state. The read circuit RCNT adjusts a voltage applied to the gate of the read transistor RTr, so that the read transistor RTr enters a conducting state (ON) or a non-conducting state (OFF). In the read operation, the read transistor RTr is caused to enter an on-state while the write transistor WTr is kept in an off-state. In this way, a read circuit RCS causes a read current to flow through the second terminal 10b of the conductive wire 10 and the MTJ element 20. A combination of the fixed magnetization direction of the reference layer 26 and the magnetization direction written to the storage layer 22 causes the resistance value of the MTJ element 20 to change. Accordingly, a read current of data causes a voltage to be generated depending on the magnetization direction of the storage layer 22, and the logic of the data can be detected based on the voltage value.

As illustrated in FIG. 2, since the direction of a spin flow Is and the direction of a spin “s” are perpendicular to each other, it is preferable for efficient action of the spin torque to use, as the reference layer 26 and the storage layer 22, a magnetic layer (hereinafter, in-plane magnetic layer) in which the magnetization direction is in a direction that is perpendicular to the stacked direction of the magnetoresistance element, that is, a direction that is parallel to the film surface. The in-plane magnetic layer generally secures magnetic anisotropy by shape anisotropy.

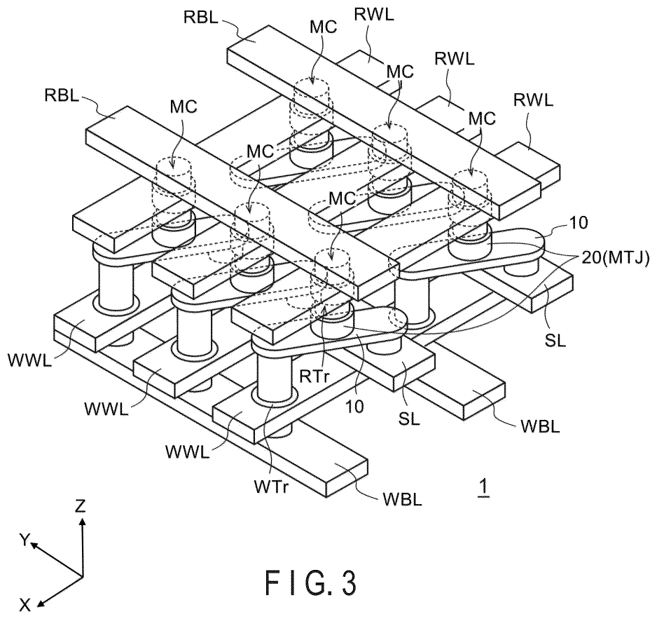

FIG. 3 is a perspective view illustrating an example configuration of the magnetic memory 1 according to the first embodiment. The magnetic memory 1 according to the embodiment includes a write word line WWL, a read word line RWL, a write bit line WBL, a read bit line RBL, the conductive wire 10, the magnetoresistance element (hereinafter also referred to as a magnetic tunnel junction (MTJ) element) 20, the write transistor WTr, and the read transistor RTr.

Here, a Z-direction, which is the first direction, is a stacked direction of wires of different types, such as the write bit line WBL, the write word line WWL, a source line SL, the read word line RWL, and the read bit line RBL. As used herein, the term “on”, e.g., when an element is described as being on or stacked on another element, means that the element may be directly on the other element, or additional intervening elements may be present therebetween. An X-direction, which is the second direction, is any direction in a first plane that intersects with (for example, is perpendicular to) the Z-direction. A Y-direction, which is the third direction, is a direction that intersects with (for example, is perpendicular to) the X-direction in the first plane.

The write bit line WBL, the write word line WWL, the source line SL, the conductive wire 10, the MTJ element 20, the read word line RWL, and the read bit line RBL are stacked in this order. The write bit line WBL, the write word line WWL, the source line SL, the read word line RWL, and the read bit line RBL are provided in layers that have different height levels in the Z-direction. Interlayer dielectrics are provided between wires of the write bit line WBL, the write word line WWL, the source line SL, the read word line RWL, and the read bit line RBL, which are electrically isolated from one another.

A plurality of write bit lines WBL, which are each the second write wire, extend (e.g., lengthwise) in the Y-direction and are arranged (e.g., spaced apart) in the X-direction. In the embodiment, the write bit line WBL is located on the lowermost layer in the Z-direction. When data is to be written to a memory cell MC, the write bit line WBL causes a current to flow through the conductive wire 10 depending on the data. For example, the write bit line WBL is made of an electrically conductive material, such as tungsten.

A plurality of write word lines WWL, which are each the first write wire, extend in the X-direction and are arranged in the Y-direction. In the embodiment, the write word line WWL is provided above the write bit line WBL in the Z-direction. When data is to be written to the memory cell MC, the write word line WWL places the write transistor WTr to a conducting state (ON) to cause a current to flow between the write bit line WBL and the conductive wire 10. The write word line WWL is also made of, for example, an electrically conductive material such as tungsten.

A plurality of source lines SL, which are each a third wire, extend in the Y-direction and are arranged in the X-direction. In the embodiment, the source line SL is provided above the write word line WWL in the Z-direction. The source line SL receives a current from the conductive wire 10 or the MTJ element 20 or causes a current to flow to the conductive wire 10 or the MTJ element 20 in the write and read operations. The source line SL is also made of, for example, an electrically conductive material such as tungsten. A plurality of source lines SL may have a fixed common voltage or may each be settable to a different voltage independently.

A plurality of conductive wires 10 are provided above the source line SL in the Z-direction. The conductive wire 10 is provided for each memory cell MC, that is, for each MTJ element 20 correspondingly. The conductive wire 10 is connected to one end of the MTJ element 20. The conductive wire 10 causes a current to flow between the write bit line WBL and the source line SL in the write operation or causes a current to flow through the MTJ element 20 between the read bit line RBL and the source line SL in the read operation. A non-magnetic conductive material, for example, tungsten is used for the conductive wire 10. Note that, in the case of a magnetic domain wall MRAM, the conductive wire 10 is composed of an electrically conductive stacked body that includes a ferromagnetic material, the magnetization direction of which is changed by a current (for example, CoFeB).

A plurality of read word lines RWL, which are each the first read wire, extend in the X-direction and are arranged in the Y-direction. In the embodiment, the read word line RWL is provided above the conductive wire 10 and the MTJ element 20 in the Z-direction. When data is to be read from the memory cell MC, the read word line RWL places the read transistor RTr to a conducting state (ON) to cause a current to flow between the read bit line RBL and the source line SL through the MTJ element 20 and the conductive wire 10. The read word line RWL is made of, for example, an electrically conductive material such as tungsten.

A plurality of read bit lines RBL, which are each the second read wire, extend in the Y-direction and are arranged in the X-direction. In the embodiment, the read bit line RBL is provided above the read word line RWL in the Z-direction. When data is to be read from the memory cell MC, the read bit line RBL causes a current to flow depending on the resistance of the MTJ element 20. The read bit line RBL is made of, for example, an electrically conductive material such as tungsten.

The MTJ element 20, which is the magnetoresistance element, is connected between a middle portion of the conductive wire 10 and the source or the drain of the read transistor RTr. One end (lower end) of the MTJ element 20 is connected to the middle portion of the conductive wire 10 and the other end (upper end) is connected to the source or the drain of the read transistor RTr. The MTJ element 20 is composed of the storage layer 22, the non-magnetic layer 24, and the reference layer 26 that are stacked in this order in the Z-direction. The configuration of the MTJ element 20 is as described with reference to FIG. 1.

In the write transistor WTr, one of the source and the drain is connected to the write bit line WBL and the other is connected to the conductive wire 10. The gate of the write transistor WTr is connected to the write word line WWL. In this way, the write circuit WCNT in FIG. 1 applies a voltage to the write word line WWL to control the write transistor WTr to turn on or off.

In the write operation, the write transistor WTr is turned on to cause a current to flow between the write bit line WBL and the conductive wire 10. The current flows as the write current through the conductive wire 10 between the write bit line WBL and the source line SL. In the write operation, the read transistor RTr is in the off-state to block a current between the read bit line RBL and the MTJ element 20.

In the read transistor RTr, one of a source and a drain is connected to the read bit line RBL and the other is connected to the upper end of the MTJ element 20. The gate of the read transistor RTr is connected to the read word line RWL. In this way, the read circuit RCNT in FIG. 1 applies a voltage to the read word line RWL to control the read transistor RTr to turn on or off.

In the read operation, the read transistor RTr is turned on to cause a current to flow between the read bit line RBL and the MTJ element 20. The current flows as a read current through the MTJ element 20 between the read bit line RBL and the source line SL. In the read operation, the write transistor WTr is in the off-state to block a current between the write bit line WBL and the conductive wire 10.

As illustrated in FIG. 3, the write transistor WTr and the read transistor RTr are provided in or on different layers in the Z-direction and disposed on opposite sides with the MTJ element 20 in between in the Z-direction. The write transistor WTr is provided at the height of the write word line WWL below the MTJ element 20. The read transistor RTr is provided at the height of the read word line RWL above the MTJ element 20. In this way, the write transistor WTr and the read transistor RTr can be separately formed to have mutually different configurations and characteristics. Configurations and characteristics of the write transistor WTr and the read transistor RTr will be described later.

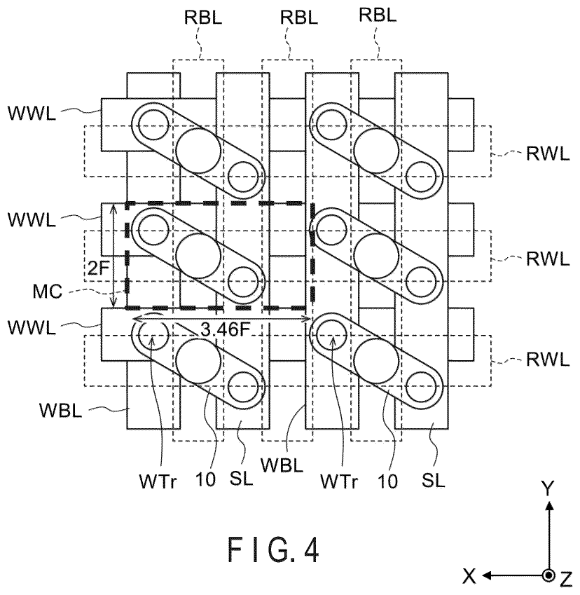

FIG. 4 is a plan view illustrating an example configuration of the magnetic memory 1 according to the first embodiment. FIG. 4 illustrates a plane of the magnetic memory 1 when viewed from or along the Z-direction. The configurations above the conductive wire 10 are indicated by dashed lines.

In an X-Y plane (first plane) that is perpendicular to the Z-direction, a plurality of write word lines WWL and a plurality of read word lines RWL extend substantially in parallel to one another in the X-direction and are arranged in the Y-direction. A plurality of write bit lines WBL and a plurality of read bit lines RBL extend substantially in parallel to one another in the Y-direction and are arranged in the X-direction. Accordingly, a plurality of write word lines WWL and a plurality of write bit lines WBL intersect with (for example, are perpendicular to) one another when viewed from the Z-direction. A plurality of read word lines RWL and a plurality of read word lines RWL intersect with (for example, are perpendicular to) one another when viewed from the Z-direction.

The source line SL extends in the Y-direction and is arranged in the X-direction.

The conductive wire 10 is provided for each memory cell MC (for each MTJ element 20) correspondingly and extends in a direction inclined relative to the X and Y-directions in the X-Y plane. The conductive wire 10 is provided from a position above the write transistor WTr to a position of a contact of the source line SL, passing below the MTJ element 20 and the read transistor RTr. Accordingly, the conductive wire 10 is provided between the write transistor WTr and the source line SL with the MTJ element 20 in the center. One end of the conductive wire 10 is connected to the source or the drain of the write transistor WTr and the other end is connected to the source line SL.

The planar size of one unit of the memory cell MC is relatively small and approximately 6.9F*² (2F×3.45F). F (feature size) denotes a feature dimension that can be processed by using lithography techniques and etching techniques. Providing the conductive wire 10 in a direction inclined relative to the X and Y-directions leaves contacts on opposite ends of the conductive wires 10 arranged in a hexagonal lattice shape. In this way, it is possible to reduce the size of the memory cell MC.

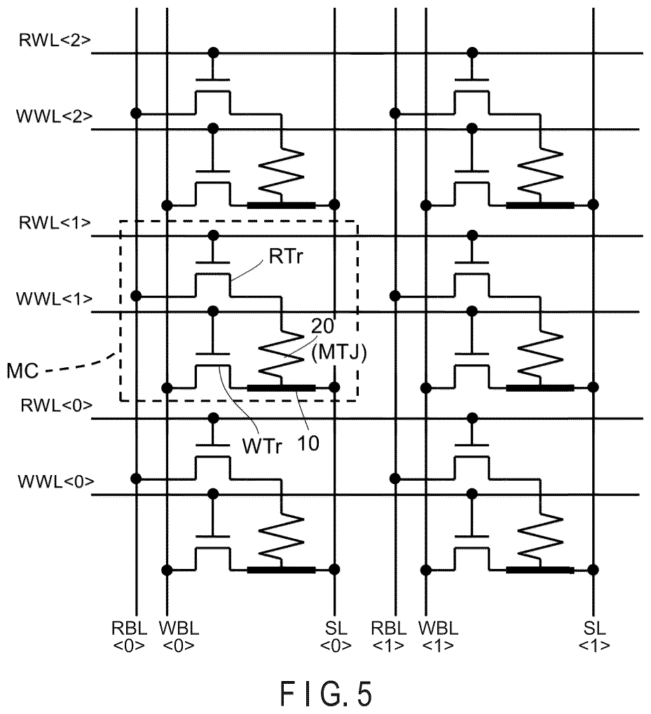

FIG. 5 is an equivalent circuit diagram illustrating an example configuration of the magnetic memory 1 according to the first embodiment. One memory cell MC includes one write transistor WTr, one read transistor RTr, and one MTJ element 20. Connection relationships among the write word line WWL, the read word line RWL, the write bit line WBL, the read bit line RBL, the conductive wire 10, the MTJ element 20, the write transistor WTr, and the read transistor RTr are as described above.

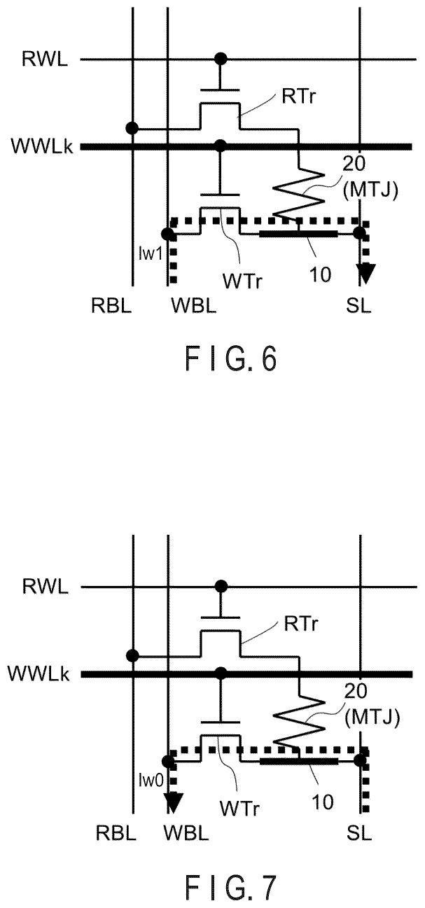

In the data write operation, a voltage is applied to a write word line WWLk (k is any of 0 to i) selected among a plurality of write word lines WWL<i> (i is an integer) to place the write transistor WTr connected to the selected write word line WWLk to an on-state. This causes the write current (Iw1 in FIG. 6 or Iw0 in FIG. 7) to flow through the write transistor WTr and the conductive wire 10 between the write bit line WBL<i> and the source line SL. The magnetization direction of the MTJ element 20 is controlled by the write current and data is written.

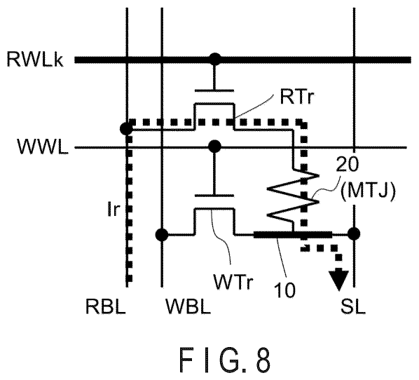

In the data read operation, a voltage is applied to a read word line RWLk selected among a plurality of read word lines RWL<i> to place the read transistor RTr connected to the selected read word line RWLk to an on-state. This causes the read current (Ir in FIG. 8) to flow through the read transistor RTr and the MTJ element 20 between the read bit line RBL<i> and the source line SL. At this time, the voltage on the read bit line RBL<i> becomes equal to a voltage that depends on the magnetization direction of the MTJ element 20. Detecting the voltage on the read bit line RBL<i> makes it possible to detect data stored in the memory cell MC.

Here, configurations and characteristics of the write transistor WTr and the read transistor RTr will be described. As described above, the write transistor WTr and the read transistor RTr are provided at different heights in the Z-direction and separately formed. This allows the write transistor WTr and the read transistor RTr to have mutually different configurations and characteristics.

For example, the write transistor WTr preferably causes a relatively large current to flow through the conductive wire 10 to write data in the MTJ element 20. FIG. 6 is a conceptual diagram illustrating the operation of writing, for example, data “1”. While the read transistor RTr is kept off, a high-level voltage is applied to the write word line WWLk to turn on the write transistor WTr. At this time, the voltage of the write bit line WBL becomes equal to the high-level voltage to cause a write current Iw1 to flow from the write bit line WBL to the write transistor WTr and the conductive wire 10. In this way, data “1” is written to the MTJ element 20. FIG. 7 is a conceptual diagram illustrating the operation of writing, for example, data “0”. In this case, while the read transistor RTr is kept off, a high-level voltage is applied to the write word line WWLk to turn on the write transistor WTr. At this time, the voltage of the write bit line WBL becomes equal to a low-level voltage to cause a write current Iw0 to flow from the source line SL to the write transistor WTr and the conductive wire 10. In this way, the MTJ element 20 is written to data “0”. At this time, the write transistor WTr preferably causes a relatively large current to flow through the conductive wire 10 to write data in the MTJ element 20. That is, to increase the write currents Iw1 and Iw0, the threshold voltage of the write transistor WTr is preferably low and an on-current is preferably large.

On the other hand, a read current Ir that is needed in the read operation of data may be smaller than the write currents Iw1 and Iw0. Accordingly, it is sufficient that the read transistor RTr causes a relatively small current to flow to the MTJ element 20 to read data from the MTJ element 20. For example, FIG. 8 is a conceptual diagram illustrating the data read operation. While the write transistor WTr is kept off, a high-level voltage is applied to the read word line RWLk to turn on the read transistor RTr. At this time, the voltage of the read bit line RBL becomes equal to the high-level voltage to cause the read current Ir to flow from the read bit line RBL to the read transistor RTr and the MTJ element 20. The read current Ir has a voltage value that depends on the resistance state of the MTJ element 20. Accordingly, the logic of the data can be detected based on the voltage value of the read current Ir. Since the read current Ir is smaller than the write currents Iw1 and Iw0, the threshold voltage of the read transistor RTr may be relatively high. Accordingly, it is possible to reduce the off-leakage current of the read transistor RTr.

As described above, in the first embodiment, the threshold voltage of the write transistor WTr is made lower than the threshold voltage of the read transistor RTr. This allows the write transistor WTr to cause relatively large write currents Iw1 and Iw0 to flow and reduce the off-leakage current of the read transistor RTr.

Any channel region of one or both of the write transistor WTr and the read transistor RTr may be made of an oxide semiconductor. A transistor based on an oxide semiconductor is characterized by being able to be formed at a low temperature of, for example, approximately 400° C. or lower and a lower off-leakage current. Accordingly, in a case in which the channel regions of both the write transistor WTr and the read transistor RTr are made of an oxide semiconductor, the entire magnetic memory 1 can be formed at a low temperature. In this case, for example, after forming metal wires such as the write word line WWL and the write bit line WBL, the write transistor WTr and the read transistor RTr can easily be formed.

Furthermore, the channel region of the write transistor WTr may be made of silicon and the channel region of the read transistor RTr may be made of an oxide semiconductor. In this case, the threshold voltage of the write transistor WTr is lowered, and the on-current relatively increases. In addition, the threshold voltage of the read transistor RTr increases, and the off-leakage current is reduced. Accordingly, it is possible to increase the write currents Iw1 and Iw0 and reduce the off-leakage current. Further in this case, the write transistor WTr, which is provided below the MTJ element 20 in the Z-direction and formed in advance of the MTJ element 20, needs to be subjected to a heat treatment at a temperature above approximately 400° C. because the channel region is made of silicon. However, this does not cause any problems because the write transistor WTr is formed before the MTJ element 20 is formed.

On the other hand, the read transistor RTr, which is provided above the MTJ element 20 in the Z-direction and formed after the MTJ element 20, can be formed at a low temperature of approximately 400° C. or lower because the channel region is made of an oxide semiconductor. Although formed after the MTJ element 20 is formed, the read transistor RTr can be formed at a low temperature, and therefore, the MTJ element 20 is not exposed to a high temperature of approximately 400° C. or higher. Accordingly, the degradation of the MTJ element 20 due to heat is inhibited, so that it is possible to improve the reliability of the magnetic memory 1.

Oxide semiconductors constituting channel regions of the write transistor WTr and/or the read transistor RTr may be made of, for example, oxide semiconductor materials including n-type or p-type material groups. Such an oxide semiconductor includes, for example, all or a part of indium, gallium, zinc, and oxygen (for example, in the form of indium-gallium-zinc oxide (IGZO)), and such channel materials may have n-type electrical conductivity. The channel materials may include, for example, tin and oxygen (for example, in the form of tin oxide), antimony and oxygen (for example, in the form of antimony oxide), indium and oxygen (for example, in the form of indium oxide), indium, tin and oxygen (for example, in the form of indium tin oxide), titanium and oxygen (for example, in the form of titanium oxide), zinc and oxygen (for example, in the form of zinc oxide), indium, zinc and oxygen (for example, in the form of indium zinc oxide), gallium and oxygen (for example, in the form of gallium oxide), titanium, oxygen and nitrogen (for example, in the form of titanium oxynitride), ruthenium and oxygen (for example, in the form of ruthenium oxide), or tungsten and oxygen (for example, in the form of tungsten oxide).

Materials constituting channel regions of the write transistor WTr and/or the read transistor RTr are, for example, preferably crystalline oxide semiconductors, whereas they may be amorphous oxide semiconductors. Specific examples of oxide semiconductor may be zinc tin oxide (ZTO), IGZO (also referred to as gallium-indium-zinc oxide (GIZO)), indium zinc oxide (IZO), ZnOx, InOx, In₂O₃, SnO₂, TiOx, ZnxOyNz, MgxZnyOz, InxZnyOz, InxGayZnzOa, ZrxInyZnzOa, HfxInyZnzOa, SnxInyZnzOa, AlxSnyInzZnaOd, SixInyZnzOa, ZnxSnyOz, AlxZnySnzOa, GaxZnySnzOa, ZrxZnySnzOa, InGaxSiyOz, and other similar materials.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory, comprising:
a first write wire;
a first read wire above the first write wire in a first direction;
a second write wire intersecting with the first write wire when viewed along the first direction;
a second read wire intersecting with the first read wire when viewed along the first direction;
a conductive wire that is electrically conductive;
a magnetoresistance element connected to the conductive wire at one end thereof;
a first transistor including a source, a drain, and a gate, wherein one of the source and the drain is connected to the second write wire, another one of the source and the drain is connected to the conductive wire, and the gate is connected to the first write wire; and
a second transistor including a source, a drain, and a gate, wherein one of the source and the drain is connected to the second read wire, another one of the source and the drain is connected to another end of the magnetoresistance element, and the gate is connected to the first read wire,
wherein a threshold voltage of the first transistor is lower than a threshold voltage of the second transistor.

2. The magnetic memory of claim 1, wherein the first transistor and the second transistor are on different layers in the first direction.

3. The magnetic memory of claim 2, wherein the first transistor and the second transistor are on opposite sides of the magnetoresistance element such that the magnetoresistance element is between the first transistor and the second transistor in the first direction.

4. The magnetic memory of claim 1, wherein:
the first transistor is in a conducting state during a data write operation, and
the second transistor is in a conducting state during a data read operation.

5. The magnetic memory of claim 1, wherein a channel region of at least one of the first transistor and the second transistor is made of an oxide semiconductor.

6. The magnetic memory of claim 5, wherein:
the channel region of one of the first transistor and the second transistor is made of an oxide semiconductor, and
the channel region of another one of the first transistor and the second transistor is made of silicon.

7. The magnetic memory of claim 6, wherein:
the channel region of the first transistor is made of silicon, and
the channel region of the second transistor is made of an oxide semiconductor.

8. The magnetic memory of claim 2, wherein:
the first write wire and the first read wire each extend in a second direction that intersects with the first direction,
the second write wire and the second read wire each extend in a third direction that intersects with the second direction, and
the conductive wire extends in a fourth direction inclined relative to the second direction and the third directions.

9. A magnetic memory, comprising:
a first write wire;
a first read wire stacked in a first direction on the first write wire;
a second write wire intersecting with the first write wire when viewed along the first direction;
a second read wire intersecting with the first read wire when viewed along the first direction;
a conductive wire that is electrically conductive;
a magnetoresistance element connected to the conductive wire at one end;
a first transistor including a source, a drain, and a gate, wherein one of the source and the drain is connected to the second write wire, another one of the source and the drain is connected to the conductive wire, and the gate is connected to the first write wire; and
a second transistor including a source, a drain, and a gate, wherein one of the source and a drain is connected to the second read wire, another one of the source and the drain is connected to another end of the magnetoresistance element, and the gate is connected to the first read wire, wherein
the first transistor and the second transistor are on different layers in the first direction, and
a channel region of at least one of the first transistor and the second transistor is made of an oxide semiconductor.

10. The magnetic memory of claim 9, wherein the first transistor and the second transistor are on opposite sides of the magnetoresistance element such that the magnetoresistance element is between the first transistor and the second transistor in the first direction.

11. The magnetic memory of claim 9, wherein:
the first transistor is in a conducting state during a data write operation, and
the second transistor is in a conducting state during a data read operation.

12. The magnetic memory of claim 9, wherein:
the channel region of one of the first transistor and the second transistor is made of an oxide semiconductor, and
the channel region of another one of the first transistor and the second transistor is made of silicon.

13. The magnetic memory of claim 12, wherein:
the channel region of the first transistor is made of silicon, and
the channel region of the second transistor is made of an oxide semiconductor.
